(19) United States
(12) Patent Application Publication
(10) Pub. No.: US 2013/0248709 A1
(43) Pub. Date: Sep. 26, 2013

(54) DEFECT INSPECTING APPARATUS

(71) Applicants: Takuma Yamamoto, Mito (JP); Takashi Hiroi, Yokohama (JP); Hiroshi Miyai, Hitachi (JP)

(72) Inventors: Takuma Yamamoto, Mito (JP); Takashi Hiroi, Yokohama (JP); Hiroshi Miyai, Hitachi (JP)

(73) Assignee: HITACHI HIGH-TECHNOLOGIES CORPORATION, Tokyo (JP)

(21) Appl. No.: 13/992,057

(22) PCT Filed: Nov. 24, 2011
(86) PCT No.: PCT/JP2011/076978

§ 371 Date: Jun. 6, 2013

(30) Foreign Application Priority Data
Jun. 12, 2010 (JP) 2010-271818

(51) Int. Cl. H01J 37/26

(52) U.S. Cl. CPC H01J 37/26
USPC 250/309

(57) ABSTRACT

A semiconductor wafer 11 is irradiated for scanning with a charged particle beam 6 so as to detect secondary charged particles 9 obtained from the wafer 11 as a result of the irradiation of the beam 6. A detected image of an inspection area obtained based on scanning information and on a detection signal derived from the secondary charged particles 9 is compared with a detected image of a reference area to find a difference therebetween. The difference is compared with a threshold value to detect a defect candidate. Defect information including positional information about the defect candidate is generated in such a manner as to include a relative position of a predetermined feature point within each of repeat patterns formed on the semiconductor wafer 11 with regard to the origin of a coordinate area established in each of these repeat patterns, and a relative position of the defect candidate with regard to the feature point. This contributes to providing a defect inspecting apparatus capable of determining defective areas for extraction by FIB more easily than before.

### TECHNICAL FIELD

This invention relates to a defect inspecting apparatus that inspects semiconductor substrates, thin film substrates, liquid crystal display devices or the like for foreign matters, flaws, defects or other irregularities.

### BACKGROUND ART

In the process of manufacturing semiconductor substrates, thin film substrates, liquid crystal display devices or the like (generically called the test objects hereunder) having circuit patterns, the test objects are inspected for foreign matters, flaws, defects or other irregularities (generically called the defect hereunder) under management to improve yield and product quality.

A known conventional technique for detecting defects of such test objects involves, for example, emitting a charged particle beam to the surface of a substrate (test object) for scanning thereby to detect any of three kinds of charged particles (secondary charged particles, back-scattering charged particles, and transmitted charged particles) coming from the top or bottom of the substrate, the result of the detection being used to obtain images in which the same patterns are compared side by side to detect any defect therein (e.g., see Patent Literature 1).

### PRIOR ART LITERATURE

### Patent Document

Patent Document 1: JP-1993-258703-A

### SUMMARY OF THE INVENTION

### Problem to be Solved by the Invention

The efforts to miniaturize the pattern sizes of semiconductor devices or the like for their higher integration have been advancing in fits and starts in recent years. Increasing technological barriers to overcome in conjunction with such miniaturization, as well as growing costs involved, have prompted rapid progress in getting semiconductor devices fabricated three-dimensionally besides being miniaturized. With the semiconductor devices increasingly fabricated three-dimensionally, it is difficult to analyze defects of each test object and identify their probable causes through observation of solely the surface of the test object in question. This has brought about a growing need for cross-sectional observations of defective areas. For example, to make a cross-sectional observation of a defective area on a test object, there exist methods for extracting by FIB (Focused Ion Beam) the defective area detected by a defect inspecting apparatus and for observing a cross-section of the specimen using SEM (Scanning Electron Microscope).

However, the pattern of the semiconductor device under test and the detected defect thereof are so minuscule that it has been difficult to determine defective areas for extraction by FIB. It has thus taken a long time to extract the defective area. As a result, the number of defective areas that can be observed has been limited, which in turn has limited the amount of relevant information to be fed back to the process of manufacturing semiconductor devices.

This invention has been made in view of the above circumstances and has an object of providing a defect inspecting apparatus capable of determining defective areas for extraction by FIB more easily than before.

### Means for Solving the Problem

In carrying out the above object, this invention provides charged particle beam irradiation means which irradiates a test object with a charged particle beam for scanning; charged particle detection means which detects secondary charged particles obtained from the test object as a result of the irradiation of the charged particle beam; defect detection means which compares a detected image of an inspection area obtained based on scanning information from the charged particle beam irradiation means and on a detection signal from the charged particle beam detection means with a detected image of a reference area to find a difference therebetween, the defect detection means further comparing the difference with a threshold value to detect a defect candidate; and information processing means which generates defect information including positional information about the defect candidate. The defect information includes a relative position of a predetermined feature point in each of repeat patterns formed on the test object with regard to the origin of a coordinate area established in each of the repeat patterns, and a relative position of the defect candidate with regard to the feature point.

### Effects of the Invention

According to this invention, it is possible to determine defective areas for extraction by FIB more easily than before.

### BRIEF DESCRIPTION OF THE DRAWINGS

FIG. 1 is an illustration outlining an overall structure of a defect inspecting apparatus embodying this invention.

FIG. 2 is an illustration showing a pattern formation on a semiconductor wafer handled by the embodiment of this invention.

FIG. 3 is an illustration showing a setting screen regarding an inspection area on a defect inspecting apparatus as a first embodiment of this invention.

FIG. 4 is an illustration showing how a defect position correction process is performed by the first embodiment.

FIG. 5 is an illustration showing defect information generated in a defect detection process performed by the defect inspecting apparatus of the first embodiment.

FIG. 6 is a processing flowchart showing a defect information generation process performed by a second embodiment of this invention to generate defect information.

FIG. 7 is an illustration showing how a defect is detected on a memory mat by the second embodiment.

FIG. 8 is an illustration showing how a defect re-detection process is performed by the second embodiment.

FIG. 9 is an illustration showing defect information generated by a defect detection process performed by the defect inspecting apparatus of the second embodiment.

FIG. 10 is an illustration showing an inspection area preparation screen of a third embodiment of this invention.

FIG. 11 is an illustration schematically showing positional relations among a die, a reference point, and a defect in connection with the third embodiment.

FIG. 12 is an illustration showing defect information generated in a defect detection process performed by the defect inspecting apparatus of the third embodiment.

### MODE FOR CARRYING OUT THE INVENTION

Explained below in reference to the accompanying drawings is how a semiconductor wafer is inspected as a test object by embodiments of this invention, the wafer being fabricated eventually into semiconductor devices.

### First Embodiment

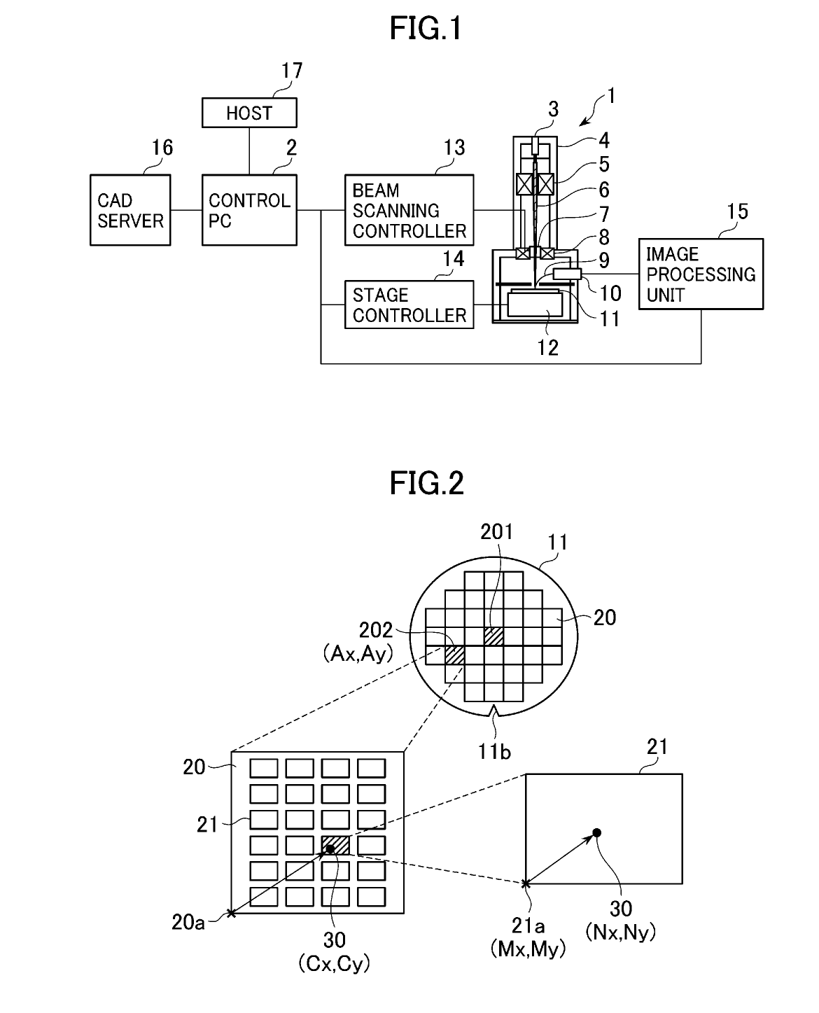

FIG. 1 is an illustration outlining an overall structure of a defect inspecting apparatus embodying this invention.

In FIG. 1, the defect inspecting apparatus of this embodiment schematically includes a SEM (Scanning Electron Microscope) 1, a control PC 2 that controls overall performance of the entire defect inspecting apparatus including the SEM 1, and a CAD server 16 that stores CAD (Computer Aided Design) information about circuit patterns formed on a semiconductor wafer (test object) 11.

The control PC 2 is connected to a high-order host 17 that controls a production system or the like including the defect inspecting apparatus. As such, the control PC 2 is configured to operate diversely in linkage with another defect inspecting apparatus or other devices. The control PC 2 further includes a display device, an input device, a storage device, etc., not shown.

The SEM 1 includes a stage 12 for mounting thereon the semiconductor wafer 11 as the test object and moving three-dimensionally the semiconductor wafer 11; an electron gun 3 which is attached to a column 4 as part of an electron optics system and which emits a charged particle beam 6 for irradiation of the semiconductor wafer 11; a condenser lens 5 and an object lens 8 for condensing the charged particle beam 6 emitted from the electron gun 3; a deflector 7 that scans the semiconductor wafer 11 with the condensed charged particle beam 6; a beam scanning controller 13 that controls the operation of the deflector 7; a charged particle detection device 10 that detects secondary charged particles 9 obtained from the semiconductor wafer as a result of the irradiation of the charged particle beam 6; an image processing unit 15 that generates images of the surface of the semiconductor wafer 11 based on irradiation information from the beam scanning controller 13 about the charged particle beam 6 and on a detection signal from the charged particle detection device 10; and a stage controller 14 that controls the position of the stage 12.

The image processing unit 15 compares a detected image of an inspection area obtained based on the scanning information (information about the scanned position) from the beam scanning controller 13 and on the detection signal from the charged particle detection device 10 with a detected image of a reference area to find a difference therebetween, the image processing unit 15 further comparing the difference with a predetermined threshold value to detect defect candidates (in a defect detection process), and thereby generating defect information (see FIG. 5 to be discussed later) including position information about the defect candidates.

FIG. 2 is an illustration showing how position coordinates are established over the semiconductor wafer 11 as a typical test object to be handled by the embodiment. In the ensuing description, an X-axis is assumed to be established in the horizontal direction and a Y-axis in the vertical direction where a notch 11b for orienting the semiconductor wafer 11 in different processes is positioned downward.

In FIG. 2, a plurality of dies 20 are formed in the X- and Y-axis directions over the semiconductor wafer 11. A plurality of memory mats 21 are further formed in the X- and Y-axis directions over each die 20. Each of the dies 20 arrayed in this manner has its coordinates defined as those of a relative position (Ax, Ay) with regard to an origin die 201. In FIG. 2, a die 202 is located two dies left of the origin die 201 and one die below it, so that the coordinates of the die 202 are given as (−2, −1).

A die coordinate system is established over the die 20, with an X-axis and a Y-axis set along the bottom edge and the leftmost edge of the die 20 respectively, the system having its origin 20a located at the point of intersection between the X-axis and the Y-axis (.e., bottom left corner of the die 20). In this die coordinate system, the position of a defect 30 on the die 20 is represented by relative coordinates (Cx, Cy) with regard to the die origin 20a.

Also, the relative coordinates of the defect 30 with regard to the die origin may be given as (Mx+Nx, My+Ny) using relative coordinates (Mx, My) of the origin 21a of the memory mat 21 containing the defect 30 with regard to the die origin 20a and relative coordinates (Nx, Ny) of the defect 30 with regard to the mat origin 21a.

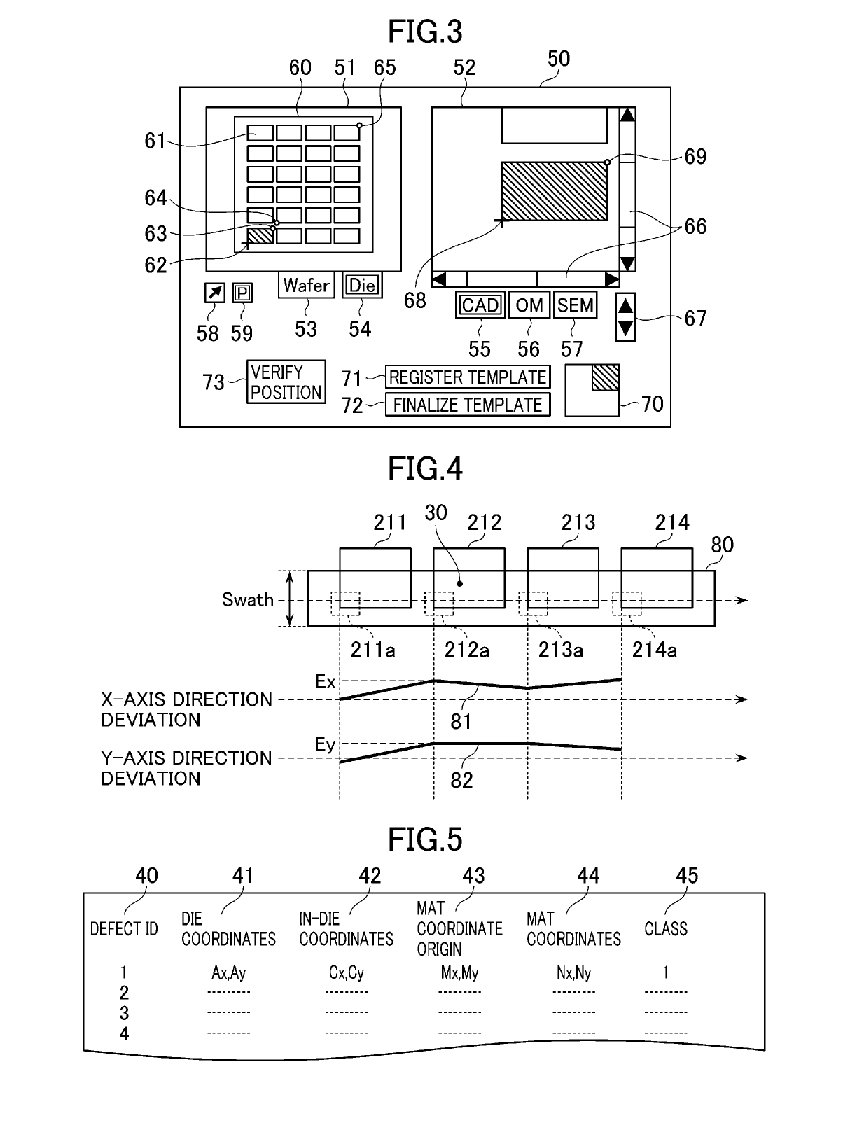

FIG. 3 is an illustration showing a setting screen regarding an inspection area on the defect inspecting apparatus of this embodiment. The setting screen 50 is displayed on a display device (not shown) of the control PC 2.

In FIG. 3, the setting screen 50 includes a map display area 51 displaying a map and an image display area 52 for displaying an image.

Located around the map display area 51 are a wafer map selection button 53 for switching the display of the map display area 51 to wafer map, a die map selection button 54 for switching to die map, an arrow button 58 for switching to area selection mode, and a point button 59 for switching to movement mode. FIG. 3 shows an example in which the die map selection button 54 is selected, with the map display area 51 displaying the die map of a die area 60 containing 6 rows by 4 columns of cell mats 61 (=24 cell mats). When the arrow button 58 is selected to switch to area selection mode allowing points on the die map to be selected in the map display area 51, one of mat corners 62 through 65 is selected. When the point button 59 is selected to switch to movement mode allowing points on the die map to be selected in the map display area 51, the image display area 33 displays an image of the position corresponding to the selected point.

Located around the image display area 52 are a CAD image selection button 55 for switching the display of the image display area 52 to CAD image, an optical microscopic image selection button 56 for switching to optical microscopic image, a SEM image selection button 57 for switching to SEM image, a slide bar 66 for moving the display range of the image display area 52, and a display magnification change button 67 for changing display magnification. FIG. 3 shows a case in which the CAD image selection button 55 is selected to allow a CAD image to be displayed in the image display area 52.

As shown in FIG. 3, with the die map selection button 54, CAD image selection button 55 and point button 59 selected, a bottom left area of the die area 60 is selected so as to display a CAD image of the mat corner 62 and its vicinity in the image display area 52. In the image display area 52, a mat corner position 68 corresponding to the mat corner 62 is selected so as to register positional information about the mat corner 62. Then in the image display area 52, a mat corner position 69 corresponding to the mat corner 63 is selected so as to register positional information about the mat corner 63. This finalizes the size of the cell mat 61. At this point, the scroll bar 66 or the display magnification change button 67 may be used as needed to display a CAD image of a desired position. Likewise, the mat corner position corresponding to the mat corner 64 is selected so as to register positional information about the mat corner 64 and thereby to finalize the array pitch of the cell mats 61. And the mat corner position corresponding to the mat corner 65 is selected so as to register positional information about the mat corner 65 and thereby to finalize the number of cell mats 61 arrayed in the die area 60.

Further, the arrow button 58 is selected to switch to area selection mode, and the mat corner 62 is selected in the map display area 51. In this state, a position verification button 73 is selected to allow a CAD image centering on the mat corner 62 to be displayed in the image display area 52. Then the SEM image selection button 57 is pressed to display a SEM image of the mat corner 62 in the image display area 51. After a template registration button 71 is selected, a mat corner 68 is selected in the SEM image. At this point, a cross mark indicating the reference point of a template image (to be discussed later) is displayed in the selected position. Then selecting a template finalizing button 72 causes the template image to be stored into a storage device (not shown) of the control PC 2 as an attachment to an inspection recipe. The template image stored at this point is displayed in a template display area 70.

A defect position correction process performed by this embodiment is explained below in reference to the accompanying drawings. FIG. 4 is an illustration showing how the defect position correction process is carried out.

The defect detection process of this embodiment involves allowing the image processing unit 15 to compare a detected image of an inspection area obtained based on the scanning information (information about the scanned position) from the beam scanning controller 13 and on the detection signal from the charged particle detection device 10 with a detected image of a reference area to find a difference therebetween, the image processing unit 15 further comparing the difference with a predetermined threshold value to detect defect candidates.

As shown in FIG. 4, if a swath 80 subject to the defect detection process includes the mat boundary at the bottom edge of memory mats 211 through 214, images of mat corners 211a through 214a of these mats are used during processing of the swath 80 to generate error information for carrying out a defect position correction process that corrects position information error caused by stage precision error or by beam deflection stemming from electrical charge distribution over the wafer.

In carrying out the defect position correction process, the image processing unit 15 reads a template image which is attached to an inspection recipe and which is stored in the storage device of the PC 2, matches the template image against those images of the mat corners 211a through 214a of the memory mats 211 through 214 which are obtained upon processing of the swath 80, and thereby calculates an X-direction deviation 81 and a Y-direction deviation 82 between the images of the mat corners 211a through 214a on the one hand and the template image on the other hand. As shown in FIG. 4, the template matching reveals that the X-direction deviation is given as Ex and the Y-direction deviation as Ey regarding the memory mat 212, one of the plurality of memory mats 21. Thus in the die coordinate system, if the coordinates of the defect 30 in the memory mat 211 are (Cx0, Cy0) before the correction process, the coordinates (Cx0, Cy0) are changed to (Cx0−Ex, Cy0−Ey) after the correction, whereby the position of the defect 30 is corrected. Also, the relative distance (Nx, Ny) of the defect 30 with regard to the origin 212a of the memory mat 212 is changed to (Cx0−Ex−Mx, Cy0−Ey−My) in the correction process.

FIG. 5 is an illustration showing defect information generated in the defect detection process performed by the defect inspecting apparatus.

In FIG. 5, the defect information is composed of defect IDs 40 allocated individually to the defects 30 detected in the defect detection process; relative positions (die coordinates) 41 of the dies 202 containing the defects 30 with regard to the origin die; relative positions (in-die coordinates) 42 of the defects 30 with regard to the origin 20a in the die coordinate system; relative positions (mat origin coordinates) 43 of the memory mats 21 containing the defects 30 with regard to the origin 20a in the die coordinate system; relative positions (mat coordinates) 44 of the memory mats containing the defects 30 with regard to the origin 21a; and classification codes (classes) 45 indicating the types of the defects. FIG. 5 shows a case in which “1” is allocated as a defect ID 40 to a defect candidate 30, with the corresponding die coordinates 41 given as (Ax, Ay), in-die coordinates 42 as (Cx, Cy), mat origin coordinates 43 as (Mx, My), mat coordinates 44 as (Nx, Ny), and class as “1.”

The operation of this embodiment configured as described above is explained below.

First, on the setting screen 50 displayed by the display device (not shown) of the control PC 2 as part of the defect inspecting apparatus, the settings regarding the inspection area are established. Then the semiconductor wafer 11 as a typical test object is placed on the stage 12 and subjected to the defect detection process whereby defect information about defect candidates is generated. The generated defect information is forwarded along with the semiconductor wafer 11 as the test object to a downstream FIB device for extraction of defective areas. The FIB device determines the position of each defect candidate based on the defect information generated by the defect inspecting apparatus of this embodiment, extracts by FIB a defective area to prepare a specimen for cross-sectional observation, and allows a cross-section of the specimen to be observed using SEM or the like.

The advantageous effects of this embodiment configured as described above are explained below.

The efforts to miniaturize the pattern sizes of semiconductor devices or the like for their higher integration have been advancing in fits and starts in recent years. Increasing technological barriers to overcome in conjunction with such miniaturization, as well as growing costs involved, have prompted rapid progress in getting semiconductor devices fabricated three-dimensionally besides being miniaturized. With the semiconductor devices increasingly fabricated three-dimensionally, it is difficult to analyze defects of each test object and identify their probable causes through observation of solely the surface of the test object in question. This has brought about a growing need for cross-sectional observations of defective areas. For example, to make a cross-sectional observation of a defective area on a test object, there exist methods for extracting by FIB (Focused Ion Beam) the defective area detected by a defect inspecting apparatus and for observing a cross-section of the specimen using SEM (Scanning Electron Microscope).

However, the pattern of the semiconductor device under test and the detected defect thereof are so minuscule that it has been difficult to determine defective areas for extraction by FIB. It has thus taken a long time to extract the defective area. As a result, the number of defective areas that can be observed has been limited, which in turn has limited the amount of relevant information to be fed back to the process of manufacturing semiconductor devices.

Under these circumstances, this embodiment prepares the defect information in such a manner as to include the relative position of a predetermined feature point (i.e., memory mat origin) within each of repeat patterns formed over the test object with regard to the origin of a coordinate area established regarding each repeat pattern, and the relative positions of defect candidates with regard to the feature points. This makes it easier to determine the defective areas for extraction by FIB.

### Second Embodiment

The second embodiment of this invention is explained below in reference to the accompanying drawings. This embodiment has the function of performing a defect re-detection process by again acquiring a detected image of the defect candidate close to a mat corner (feature point), to be discussed later. In the ensuing description, the same members as those used in the first embodiment will not be explained further.

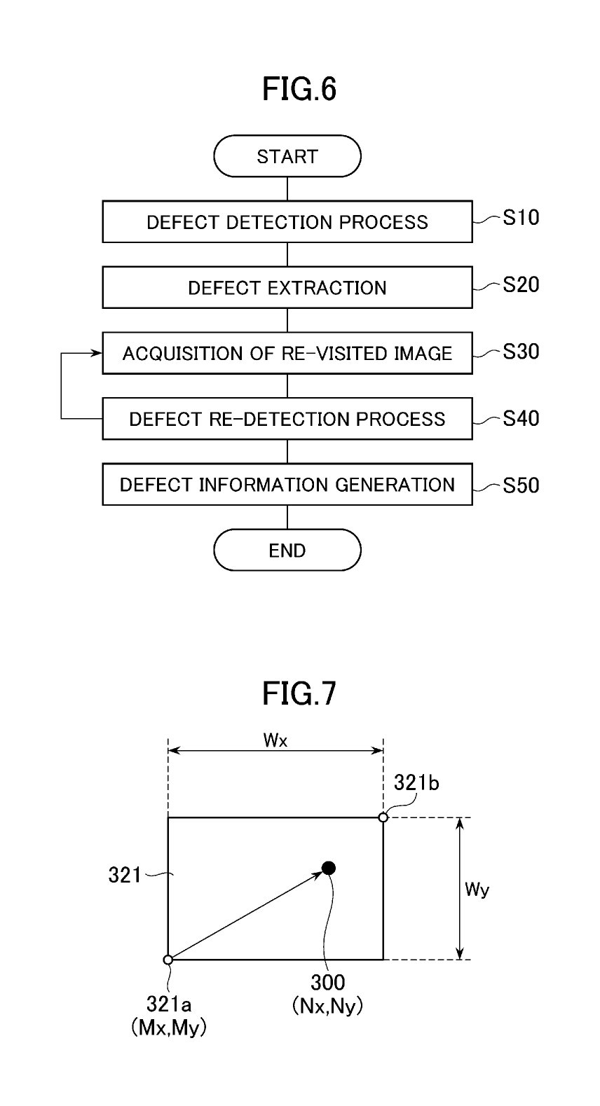

FIG. 6 is a flowchart showing how a defect information generation process is performed by this embodiment for generating defect information.

Given an instruction to start the defect information generation process, the defect inspecting apparatus of this embodiment performs the defect detection process on the test object (step S10). The control PC 2 acquires processing information from the defect detection process and, from among the defects detected through the defect detection process, extracts the defect close to a memory mat corner (step S20). The control PC 2 acquires a re-visited image of the defect extracted in step S20 (step S30), and again performs the defect detection process using the re-visited image (step S40). The control PC 2 performs steps S30 and S40 on all defects extracted in step S20. Then the control PC 2 generates defect information including information about the defect candidates detected in the defect re-detection process of step S40 (step S50), and terminates the processing.

Each of the steps constituting the defect information generation process discussed above is explained below in more detail.

### (Extraction of Defects: Step S20)

FIG. 7 shows how a defect 300 is detected from a given memory mat 321. Suppose that the mat origin is given as (Mx, My) and that the defect 300 is detected in a relative position (Nx, Ny) with regard to a mat origin 321 of the memory mat 321 measuring Wx and Wy in the horizontal and vertical directions, respectively. In this case, the distance from the leftmost edge of the memory mat 321 to the defect 300 is defined as Nx and the distance from the rightmost edge of the memory mat 321 to the defect 300 as (Wx−Nx). Likewise, the distance from the bottom edge of the memory mat 321 to the defect candidate 300 is defined as Ny and the distance from the top edge of the memory mat 321 as (Wy−Ny). If it is assumed here that Nx>(Wx−Nx) and that Nx>(Wy−Ny), the mat corner closest to the defect 300 is the top right mat corner 321b of the memory mat 321, and the coordinates of the mat corner 321b are given as (Mx+Wx, My+Wy). And the distance from the mat corner 321b to the defect 300 is given as (Wx−Nx) in the X-axis direction and (Wy−Ny) in the Y-axis direction.

Here, to obtain a re-visited image containing both the defect and the mat corner, the distances from the mat corner to the defect in both the X-axis and the Y-axis directions need to be shorter than the field of view of the re-visited image. For this reason, the larger of the two distances (Wx−Nx) and (Wy−Ny) is used as an evaluation value of the distance of the defect 300 from the mat corner. The evaluation values of the distances of all defects from the mat corners are then obtained, and as many re-visited images as the number of defects established by the recipe are acquired in order of growing evaluation values of the defects. In this case, it is possible to set the recipe in such a manner that the defects of which the re-visited images are to be obtained are selected from those defects not exceeding a threshold evaluation value of the distance from the mat corner as stipulated by the recipe, the selection being made in accordance with the feature quantities of the defect such as brightness and size.

### (Defect Re-Detection Process/Acquisition of Re-Visited Images: Steps S30 and S40)

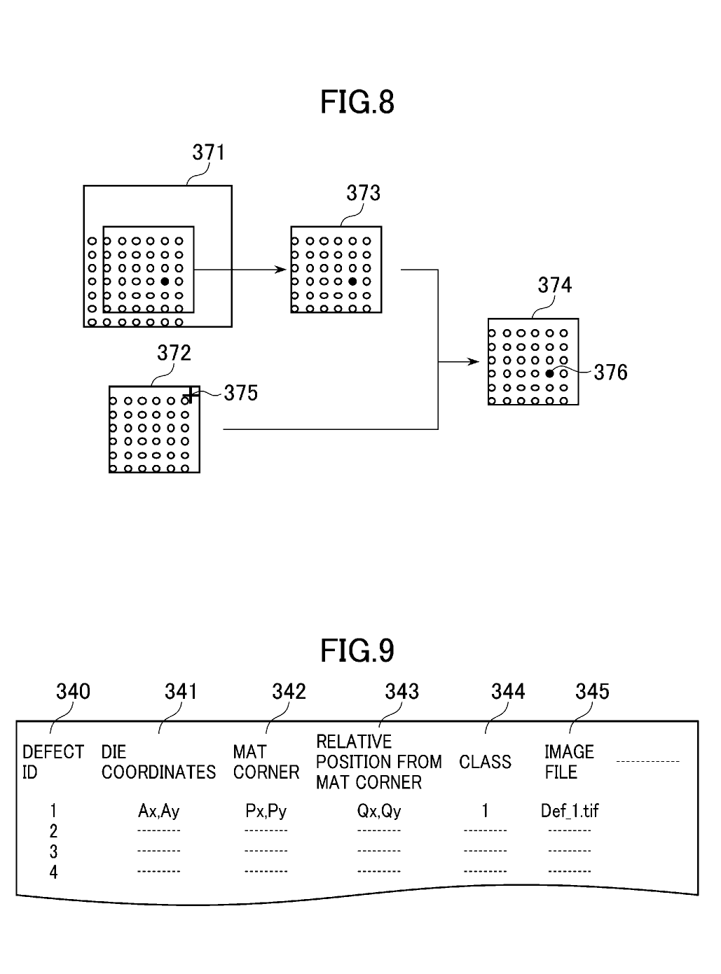

FIG. 8 is an illustration showing how the defect re-detection process is performed. In the field of view containing a defect candidate and a mat corner, a re-revisited image 371 is obtained based on the optical conditions established beforehand by the inspection recipe. Of the template images of memory mat corners obtained upon preparation of the recipe and attached to the recipe in storage, a template image 372 of the mat corner close to the defect is retrieved from the memory. In the template image 372, a mat corner 375 is assumed to have been registered by clicking on the image with a mouse during preparation of the recipe. Then an extraction image 373 is extracted from that part of the re-visited image 371 which corresponds to the template image through image matching using normalized correlation. The extraction image 373 is matched against the template image 372 to create a contrast image 374 therebetween. In the contrast image 374, the point of which the brightness is the highest is determined as the defect. If it is assumed here that the coordinates of the mat corner 375 in the template image 372 are given as (Sx, Sy) and the coordinates of a defect candidate 376 in the contrast image 374 as (Tx, Ty), the distance from the mat corner to the defect candidate 376 is defined as (Sx−Tx) in the X-axis direction and (Sy−Ty) in the Y-axis direction.

### (Generation of Defect Information: Step S50)

FIG. 9 is an illustration showing defect information generated by this embodiment. In FIG. 9, the defect information indicates the position of each in-die defect using mat corner coordinates (Px, Py) and the relative position (Qx, Qy) with regard to the mat corner. While the defect information generated by this embodiment shows the mat corner coordinates to be (Px, Py)=(Mx+Wx, My+Wy) and the relative position to be (Qx, Qy)=(Nx−Wx, Ny−Wy) with regard to the mat corner, the relative position with regard to the mat corner shows that the defect is located left of the corner if the X-axis direction is prefixed with a minus sign and right of the corner if the X-axis direction is prefixed with a plus sign. In the Y-axis direction, a minus sign prefix shows the defect to be located under the corner and a plus sign prefix shows the defect to be located above the corner.

Regarding a defect re-detected using a re-visited image, its relative position (Qx, Qy) calculated with regard to the mat corner upon inspection is replaced with the position (Tx−Sx, Ty−Sy) before being recorded to the defect information. Also in the defect information, file name information about the re-visited image 371 is recorded in linkage with the defect ID in question. The defect information and the re-visited image 371 are transmitted to the host 17 via a network, and are delivered from the host 17 to a review SEM or FIB device as needed.

The other structures and operations of this embodiment are the same as those of the first embodiment. Configured as described above, this embodiment also provides advantageous effects similar to those of the first embodiment.

### Third Embodiment

The third embodiment of this invention is explained below in reference to the accompanying drawings. This embodiment is configured to set as the feature points those positions on a test object which have a shape that matches a predetermined reference pattern. In the ensuing description, the same members as those used in the first embodiment will not be explained further.

This embodiment involves detecting a defect by performing a step-and-repeat operation to acquire images of the inspection area established in each die for comparison between the acquired images (die comparison).

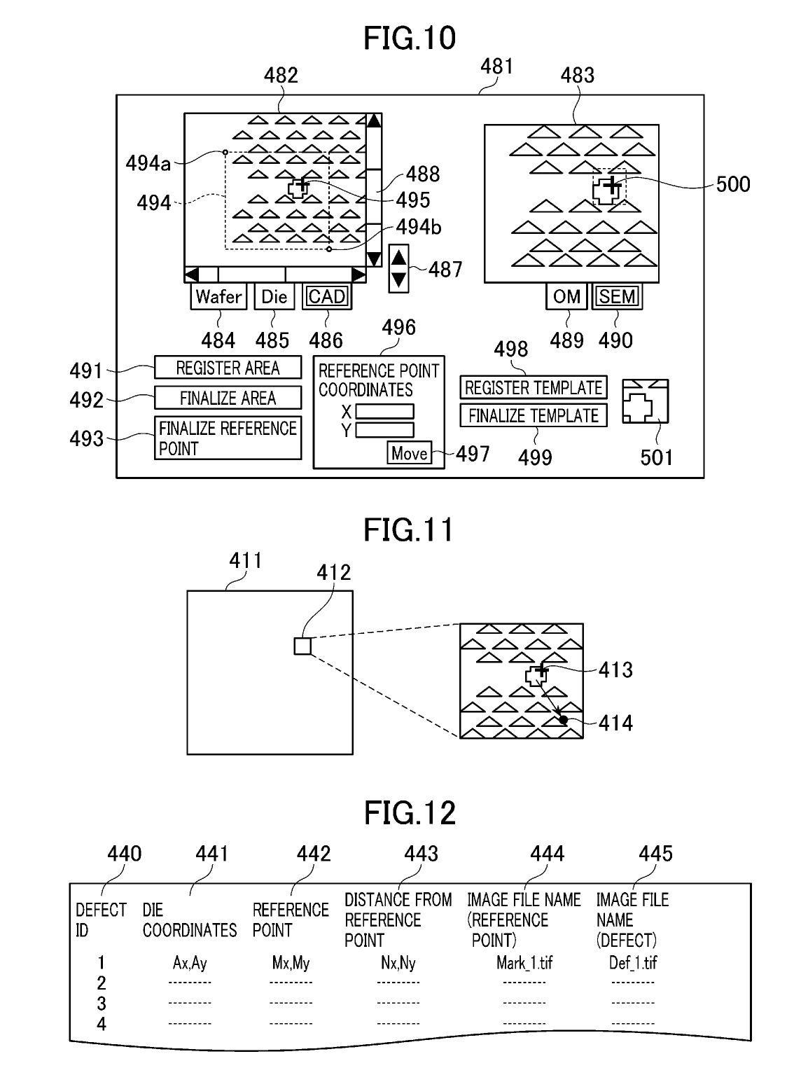

FIG. 10 is an illustration showing an inspection area preparation screen of this embodiment. In FIG. 10, a map display area 482 and an image display area 483 are shown provided on a GUI 481. In the map display area 482, switchover among wafer map display, die map display, and CAD data display can be made using a wafer map selection button 484, a die map selection button 485, and a CAD selection button 486. FIG. 10 shows a state in which CAD data display is selected, with the CAD selection button displayed in a highlighted manner. Also, the magnification of the map to be displayed can be changed using a display magnification change button 487, and the display range can be shifted using a slide bar 488. In the image display area 483, switchover between an optical microscopic image and a SEM image can be made for display using an optical microscopic image selection button 489 and a SEM image selection button 490. FIG. 10 shows a state in which a SEM image is selected, with the SEM image selection button 490 displayed in a highlighted manner.

With the CAD selection button 486 displayed in a highlighted manner as shown in FIG. 10, registration of an inspection area is started by pressing an area registration button 491. In the map display area 482, the CAD data about the area in which to set the inspection area is displayed using the display magnification change button 487 and slide bar 488. In the map display area 482, a top left point 494a and a bottom right point 494b of the inspection area are clicked to set an inspection area 494, and the points are finalized using an area finalizing button 492. Then in the map display area 482, a reference point 495 is clicked and is finalized using a reference point finalizing button 493. This causes the coordinates of the reference point to be displayed in a reference point coordinate display area 496. In this state, a movement button 497 is pressed to display an image of the reference point 495 in the image display area 483. With a template registration button 498 pressed, a reference point 500 is clicked on the SEM image. At this point, the clicked position displays a cross mark indicating the template reference point 500 and a frame indicative of the template range. A template finalizing button 499 is pressed to store the template image and template position information into the memory of the control PC. The template image stored here is displayed in a template display area 501 on the GUI.

FIG. 11 is an illustration schematically showing positional relations among a die, a reference point, and a defect. FIG. 12 is an illustration showing defect information generated in the defect detection process performed by the defect inspecting apparatus.

The defect information is generated as positional information about a defect 414 composed of the relative coordinates (Mx, My) of a reference point (feature point) 413 in an inspection area 412 set on a die 411 with regard to the die origin and the relative coordinates (Nx, Ny) of the defect 414 with regard to the reference point 413. Also attached to the defect information for storage are a template image 444 (image file name: Mark_{—}1.tif) and a defect image 445 (image file name: Def_{—}1.tif); the file names of the template image 444 and defect image 445 of each defect candidate are described in the defect information. When the defect information is output in this manner, a downstream review SEM or FIB device can move the view to a nearby defect candidate following position correction at the reference point using the template image. This makes it possible easily to bring infinitesimal defects that are difficult to detect from images into the center of the visual field of a highly magnified image.

The other structures and operations of this embodiment are the same as those of the first embodiment. Configured as described above, this embodiment also provides advantageous effects similar to those of the first embodiment.

### DESCRIPTION OF REFERENCE NUMERALS

1 SEM (Scanning Electron Microscope)
2 Control PC
3 Electron gun
4 Column
5 Condenser lens
6 Charged particle beam
7 Deflector
8 Object lens
9 Secondary charged particles
10 Charged particle detection device
11 Semiconductor wafer
12 Stage
13 Beam scanning controller
14 Stage controller
15 Image processing unit
16 CAD server
17 Host
20 Die
21 Memory mat
30 Defect candidate
40 Defect ID
41 Die coordinates
42 In-die coordinates
43 Mat origin coordinates
44 Mat coordinates
45 Class
50 Setting screen
51 Map display area
52 Image display area
70 Template display area

1. A defect inspecting apparatus comprising:
charged particle beam irradiation means which irradiates a test object with a charged particle beam for scanning;
charged particle detection means which detects secondary charged particles obtained from the test object as a result of the irradiation of the charged particle beam;
defect detection means which compares a detected image of an inspection area obtained based on scanning information from the charged particle beam irradiation means and on a detection signal from the charged particle beam detection means with a detected image of a reference area to find a difference therebetween, the defect detection means further comparing the difference with a threshold value to detect a defect candidate; and
information processing means which generates defect information including positional information about the defect candidate;
wherein the defect information includes:
a relative position of a predetermined feature point in each of repeat patterns formed on the test object with regard to the origin of a coordinate area established in each of the repeat patterns; and
a relative position of the defect candidate with regard to the feature point.

2. The defect inspecting apparatus according to claim 1, wherein the feature point is the origin of a coordinate system established in each of repeat patterns established further in each of the repeat patterns.

3. The defect inspecting apparatus according to claim 1, wherein the feature point is the closest to the defect candidate of the corners of boundaries delimiting the circumference of each of the repeat patterns established further in each of the repeat patterns.

4. The defect inspecting apparatus according to claim 1, wherein the feature point is a part of a pattern formed within the repeat patterns, the part having a shape matching that of a predetermined reference pattern.

5. The defect inspecting apparatus according to claim 1, wherein the defect information includes as correction information the difference in positional information between a detected image of the origin of a coordinate area established in each of the repeat patterns established further in each of the repeat patterns and a predetermined reference pattern of the origin.

6. The defect inspecting apparatus according to claim 1, wherein the detected image of the area including the defect candidate is again obtained based on the defect information, the detected image being used to detect the defect candidate.

7. The defect inspecting apparatus according to claim 4, wherein the defect information includes the reference pattern.
